(19) United States
(12) Patent Application Publication
(10) Pub. No.: US 2025/0105097 A1
(43) Pub. Date: Mar. 27, 2025

(54) SEMICONDUCTOR PACKAGE INCLUDING A DUMMY CHIP AND METHOD OF MANUFACTURING THE SAME

(71) Applicant: SAMSUNG ELECTRONICS CO., LTD., SUWON-SI (KR)

(72) Inventors: Yeongseon KIM, Suwon-si (KR); JUHYEON KIM, Suwon-si (KR)

(21) Appl. No.: 18/670,378

(22) Filed: May 21, 2024

(30) Foreign Application Priority Data
Sep. 21, 2023 (KR) 10-2023-0126463

(51) Int. Cl. H01L 23/48; H01L 23/00; H01L 23/28; H01L 23/498; H01L 25/065

(52) U.S. Cl. CPC H01L 23/481; H01L 23/28; H01L 23/49816; H01L 24/08; H01L 24/16; H01L 25/0652; H01L 2224/08145; H01L 2224/08225; H01L 2224/16225

(57) ABSTRACT

A semiconductor package includes a first chip, a second chip on an active surface of the first chip, a dummy chip on the active surface of the first chip, a mold layer on the active surface of the first chip and enclosing the second chip and the dummy chip, and a conductive post vertically penetrating the mold layer proximate to the second chip and the dummy chip to be coupled to the active surface of the first chip. An active surface of the second chip and an active surface of the dummy chip may be in direct contact with the active surface of the first chip. The dummy chip may include a first via. The second chip includes a second via chip. A width of the first via is larger than a width of the second via.

### CROSS-REFERENCE TO RELATED APPLICATIONS

This U.S. non-provisional patent application claims priority under 35 U.S.C. § 119 to Korean Patent Application No. 10-2023-0126463, filed on Sep. 21, 2023, in the Korean Intellectual Property Office, the entire contents of which are hereby incorporated by reference.

### TECHNICAL FIELD

The present disclosure relates to a semiconductor package and, more specifically to a semiconductor package including a dummy chip and a method of fabricating the same.

### DISCUSSION OF THE RELATED ART

In light of recent advancements in the electronics industry, the demand for high-performance, high-speed, and compact electronic components has been steadily increasing. As a result, there is a development of packaging technologies that allow for the mounting of multiple semiconductor chips within a single package.

A semiconductor package is configured to facilitate the use of an integrated circuit chip as a component in an electronic product. In general, the semiconductor package includes a printed circuit board (PCB) and a semiconductor chip, which is mounted on the PCB and is electrically connected to the PCB by bonding wires or bumps. With the recent development of the electronics industry, semiconductor package technology is developing in various ways with the goal of miniaturization, weight reduction, and manufacturing cost reduction. Furthermore, as the utilization of this technology expands to different fields, including mass storage devices, several types of semiconductor packages are emerging.

### SUMMARY

A semiconductor package includes a first semiconductor chip, a second semiconductor chip disposed on an active surface of the first semiconductor chip, a dummy chip disposed on the active surface of the first semiconductor chip and horizontally spaced apart from the second semiconductor chip, a mold layer disposed on the active surface of the first semiconductor chip and enclosing both the second semiconductor chip and the dummy chip, and a conductive post vertically penetrating the mold layer proximate to the second semiconductor chip and the dummy chip that is coupled to the active surface of the first semiconductor chip. An active surface of the second semiconductor chip and an active surface of the dummy chip are in direct contact with the active surface of the first semiconductor chip. The dummy chip includes a first via vertically penetrating the dummy chip, the dummy chip being exposed to a region on a top surface of the dummy chip. The second semiconductor chip includes a second via vertically penetrating the second semiconductor chip, the second semiconductor chip being exposed to a region on a top surface of the second semiconductor chip. A first width of the first via is larger than a second width of the second via.

A semiconductor package includes a redistribution substrate, a first semiconductor chip disposed on the redistribution substrate, a dummy chip disposed on the redistribution substrate and horizontally spaced apart from the first semiconductor chip, a second semiconductor chip disposed on the first semiconductor chip and the dummy chip, a mold layer filling a space between the redistribution substrate and the second semiconductor chip, and outer terminals disposed on a bottom surface of the redistribution substrate. The first semiconductor chip includes a first semiconductor substrate, a first circuit layer disposed on the first semiconductor substrate, first pads disposed on a top surface of the first circuit layer, and first vias vertically penetrating the first semiconductor substrate and coupled to the first circuit layer. The dummy chip includes a second semiconductor substrate, second pads disposed on the second semiconductor substrate, and second vias vertically penetrating the second semiconductor substrate and electrically connected to the second pads. The first pads and the second pads are in contact with third pads of the second semiconductor chip, and a width of the second vias is 5 to 50 times larger than a width of the first vias.

A semiconductor package includes a redistribution substrate, a first semiconductor chip and a dummy chip disposed on the redistribution substrate and spaced apart from each other, a second semiconductor chip covering the first semiconductor chip and the dummy chip, a mold layer filling a space between the redistribution substrate and the second semiconductor chip, and a conductive post vertically penetrating the mold layer and connecting the redistribution substrate to the second semiconductor chip. The first semiconductor chip includes a first semiconductor substrate, in which an integrated circuit is formed on a top surface facing the second semiconductor chip, and a first circuit layer disposed on the top surface of the first semiconductor substrate and electrically connected to the integrated circuit. The dummy chip includes the second semiconductor substrate, a second circuit layer disposed on a top surface of the second semiconductor substrate, and first vias vertically penetrating the second semiconductor substrate and connected to the second circuit layer. The first vias include protruding portions extended to a region below a bottom surface of the second semiconductor substrate. A width of the first vias is substantially equal to or larger than a width of the conductive post.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a cross-sectional view illustrating a semiconductor package according to an embodiment of the inventive concept.

FIG. 2 is an enlarged cross-sectional view illustrating a portion ‘A’ of FIG. 1.

FIG. 3 is an enlarged cross-sectional view illustrating a portion ‘B’ of FIG. 1.

FIGS. 4 to 6 are cross-sectional views illustrating semiconductor package according to an embodiment of the inventive concept.

FIGS. 7 to 13 are cross-sectional views illustrating a method of fabricating a semiconductor package, according to an embodiment of the inventive concept.

### DETAILED DESCRIPTION

Example embodiments of the inventive concepts will now be described more fully with reference to the accompanying drawings, in which example embodiments are shown.

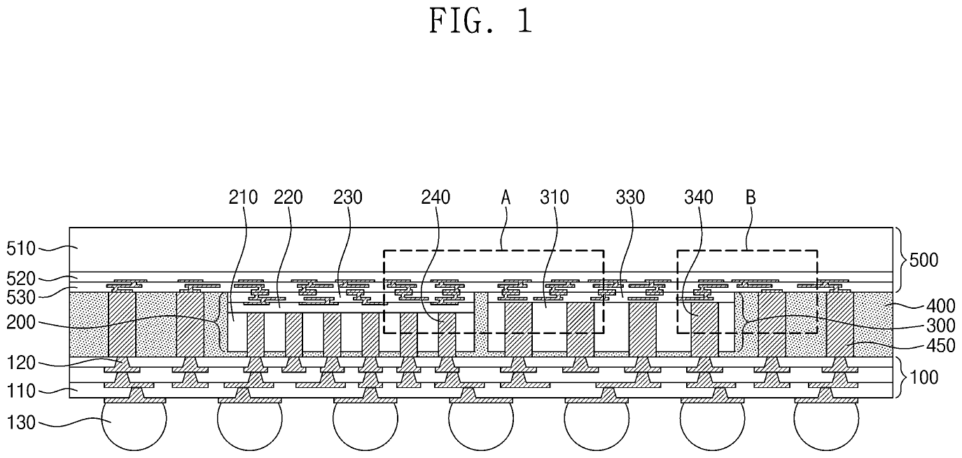

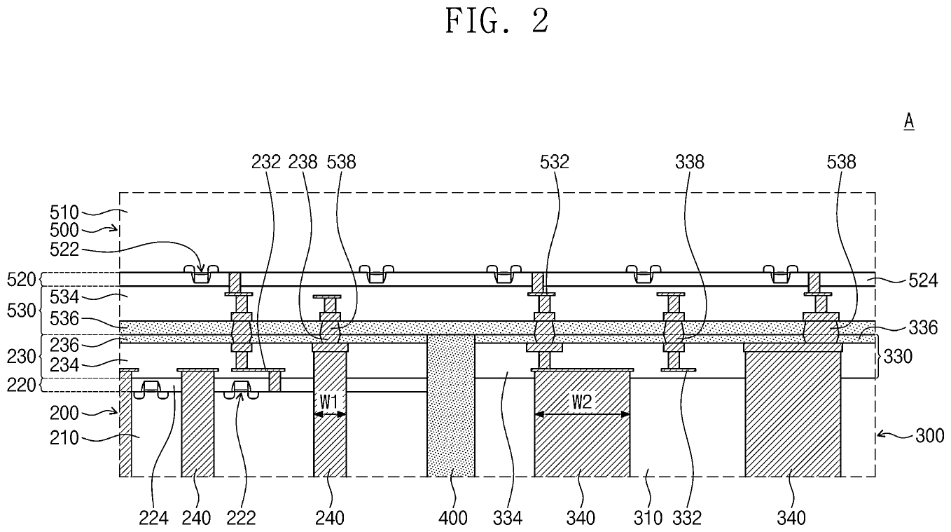

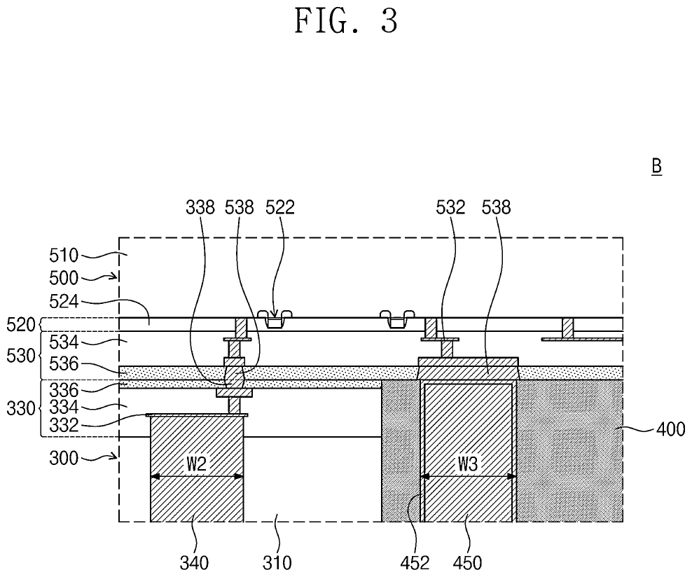

FIG. 1 is a cross-sectional view illustrating a semiconductor package according to an embodiment of the inventive concept. FIG. 2 is an enlarged cross-sectional view illustrating a portion ‘A’ of FIG. 1. FIG. 3 is an enlarged cross-sectional view illustrating a portion ‘B’ of FIG. 1.

Referring to FIGS. 1 to 3, a redistribution substrate 100 may be provided. The redistribution substrate 100 may include one or more substrate interconnection layers, which are sequentially stacked. Each of the substrate interconnection layers may include a redistribution insulating layer 110 and a redistribution conductive pattern 120 in the redistribution insulating layer 110. In the case where a plurality of substrate interconnection layers are provided, the redistribution conductive pattern 120 of one substrate interconnection layer may be electrically connected to the redistribution conductive pattern 120 of another substrate interconnection layer adjacent thereto. Hereinafter, the redistribution insulating layer 110 and the redistribution conductive pattern 120 will be described with reference to one of the substrate interconnection layers.

A top surface of the redistribution insulating layer 110 in the uppermost one of the substrate interconnection layers may be substantially flat. For example, the top surface of the redistribution substrate 100 may be substantially flat. The redistribution insulating layer 110 may include a photoimageable insulating material (PID). For example, the photoimageable dielectric materials may include photoimageable polyimide (PI), polybenzoxazole (PBO), phenol-based polymers, and/or benzocyclobutene-based polymers. In an embodiment, the redistribution insulating layer 110 may include an insulating material. For example, the redistribution insulating layer 110 may be formed of or may include silicon oxide (SiO), silicon nitride (SiN), silicon oxynitride (SiON), silicon carbonitride (SiCN), and/or insulating polymers.

The redistribution conductive pattern 120 may be provided on the redistribution insulating layer 110. The redistribution conductive pattern 120 on the redistribution insulating layer 110 may be horizontally extended. The redistribution conductive pattern 120 may be an element for an internal redistribution of the substrate. The redistribution conductive pattern 120 may include a conductive material. For example, the redistribution conductive pattern 120 may be formed of or may include copper (Cu) and/or aluminum (Al).

The redistribution conductive pattern 120 may have a damascene structure. For example, the redistribution conductive pattern 120 may include a head portion and a tail portion, which are connected to form a single object. The head and tail portions of the redistribution conductive pattern 120 may have a cross-section of an inverted ‘T’ shape.

The head portion of the redistribution conductive pattern 120 may be a wire or pad portion which is used to horizontally expand an interconnection line in the redistribution substrate 100. The head portion may be provided on a bottom surface of the redistribution insulating layer 110. For example, the head portion may be extended to a region on the bottom surface of the redistribution insulating layer 110 and may have a protruding shape. The redistribution conductive pattern 120 in the lowermost one of the substrate interconnection layers may be exposed to a region below the bottom surface of the lowermost one of the redistribution insulating layers 110 (i.e., the bottom surface of the redistribution substrate 100). The exposed redistribution conductive pattern 120 may be used as substrate pads, which are coupled to outer terminals 130. Alternatively, pads for the coupling with the outer terminals 130 may be further provided on the bottom surface of the redistribution substrate 100, and such pads may be coupled to the exposed redistribution conductive pattern 120.

The tail portion of the redistribution conductive pattern 120 may be a via portion that is used to vertically connect interconnection lines in the redistribution substrate 100 to each other. The tail portion may be coupled to another substrate interconnection layer thereon. For example, the tail portion of the redistribution conductive pattern 120 may be extended from a top surface of the head portion to penetrate the redistribution insulating layer 110 and may be coupled to the head portion of the redistribution conductive pattern 120 in another substrate interconnection layer thereon. The tail portion of the redistribution conductive pattern 120 in the uppermost one of the substrate interconnection layers may penetrate the redistribution insulating layer 110 and may be exposed to a region on the top surface of the redistribution substrate 100 (e.g., the top surface of the redistribution insulating layer 110 in the uppermost one of the substrate interconnection layers). The redistribution conductive pattern 120 in the uppermost one of the substrate interconnection layers may be electrically coupled to a first semiconductor chip 200, a dummy chip 300, and conductive posts 450, which will be described below.

The outer terminals 130 may be provided on the bottom surface of the redistribution substrate 100. The outer terminals 130 may be coupled to the redistribution conductive pattern 120 in the lowermost one of the substrate interconnection layers. The outer terminals 130 may include solder balls or solder bumps, and the semiconductor package may be classified into a ball grid array (BGA) package, a fine ball-grid array (FBGA) package, or a land grid array (LGA) package, depending on the type and arrangement of the outer terminals 130.

The first semiconductor chip 200 may be disposed on the redistribution substrate 100. The first semiconductor chip 200 may have a front surface and a rear surface. Hereinafter, in the present specification, the front surface may be defined as a surface of a semiconductor chip, which is an active surface for integrated devices, and on which interconnection wires or pads are formed, and the rear surface may be defined as a surface that is opposite to the front surface of the semiconductor chip. The first semiconductor chip 200 may be placed such that the rear surface thereof faces the redistribution substrate 100. For example, the first semiconductor chip 200 may be disposed on the redistribution substrate 100 in a face-up manner.

The first semiconductor chip 200 may include a first semiconductor substrate 210, a first circuit layer 220, a first interconnection layer 230, and first vias 240.

The first semiconductor substrate 210 may be provided. The first semiconductor substrate 210 may include a semiconductor material. For example, the first semiconductor substrate 210 may be a single-crystalline silicon substrate.

The first semiconductor substrate 210 may have a top surface and a bottom surface, which are opposite to each other. The top surface of the first semiconductor substrate 210 may be a front surface of the first semiconductor substrate 210, and the bottom surface may be a rear surface of the first semiconductor substrate 210. Here, the front surface of the first semiconductor substrate 210 may be defined as a surface of the first semiconductor substrate 210, on which semiconductor devices, interconnection lines, or pads are formed or mounted, and the rear surface of the first semiconductor substrate 210 may be defined as a surface that is opposite to the front surface. The rear surface of the first semiconductor substrate 210 may face the redistribution substrate 100.

The first circuit layer 220 may be disposed on the first semiconductor substrate 210. The first circuit layer 220 may be disposed on the top surface of the first semiconductor substrate 210. The first circuit layer 220 may include a first semiconductor device 222 and a first interlayer insulating layer 224.

The first semiconductor device 222 may include first transistors, which are formed or provided on the top surface of the first semiconductor substrate 210. In an embodiment, each of the first transistors may include source and drain regions, which are formed in an upper portion of the first semiconductor substrate 210, a gate electrode, which is disposed on the top surface of the first semiconductor substrate 210, and a gate insulating layer interposed between the first semiconductor substrate 210 and the gate electrode. FIG. 2 illustrates an example, in which two first transistors are provided, but the inventive concept is not necessarily limited to this example. The first semiconductor device 222 may include a plurality of the first transistors. The first semiconductor device 222 may include a memory circuit. The first semiconductor device 222 may include a shallow device isolation pattern, which is provided in the first semiconductor substrate 210, and may be used as a part of a memory cell. For example, the first semiconductor chip 200 may be a memory chip. Alternatively, the first semiconductor device 222 may include a logic circuit. As an example, the first semiconductor chip 200 may be a logic chip. In an embodiment, the first semiconductor device 222 may include a passive device (e.g., a capacitor).

The top surface of the first semiconductor substrate 210 may be covered with the first interlayer insulating layer 224. The first semiconductor device 222 may be buried in the first interlayer insulating layer 224, which is provided on the top surface of the first semiconductor substrate 210. Here, the first interlayer insulating layer 224 may be provided on the first semiconductor device 222 to cover the first semiconductor device 222. In an embodiment, the first semiconductor device 222 might not be exposed to the outside by the first interlayer insulating layer 224. A side surface of the first interlayer insulating layer 224 may be aligned to a side surface of the first semiconductor substrate 210. In an embodiment, the first interlayer insulating layer 224 may be formed of or may include silicon oxide (SiO), silicon nitride (SiN), and/or silicon oxynitride (SiON). Alternatively, the first interlayer insulating layer 224 may include a low-k dielectric material. As used herein, the term “low-k” may be understood to mean a material having a dielectric constant that is lower than that of silicon oxide. The first interlayer insulating layer 224 may have a mono- or multi-layered structure.

The first interconnection layer 230 may be disposed on the first circuit layer 220. The first interconnection layer 230 may be disposed on a top surface of the first circuit layer 220. The first interconnection layer 230 may include a first interconnection portion 232 and a second interlayer insulating layer 234.

A top surface of the first interlayer insulating layer 224 may be covered with the second interlayer insulating layer 234. A side surface of the second interlayer insulating layer 234 may be aligned to the side surface of the first semiconductor substrate 210. The second interlayer insulating layer 234 may be formed of or may include silicon oxide (SiO), silicon nitride (SiN), and/or silicon oxynitride (SiON). Alternatively, the second interlayer insulating layer 234 may be formed of or may include a low-k dielectric material. The second interlayer insulating layer 234 may have a mono- or multi-layered structure. In the case where the second interlayer insulating layer 234 has the multi-layered structure, each of first interconnection layers, which will be described below, may be provided in a single insulating layer, and an etch stop layer may be interposed between the insulating layers. For example, the etch stop layers may be provided on bottom surfaces of the insulating layers. The etch stop layer may be formed of or may include silicon nitride (SiN), silicon oxynitride (SiON), and/or silicon carbonitride (SiCN).

The first interconnection portion 232 may include first interconnection patterns buried in the second interlayer insulating layer 234. The first interconnection patterns may be used for horizontal interconnection. As an example, the first interconnection patterns, which are placed at the same vertical level, may constitute a single first interconnection layer. The first interconnection patterns may be positioned between top and bottom surfaces of the second interlayer insulating layer 234. Some of the first interconnection patterns may be disposed in an upper portion of the second interlayer insulating layer 234. For example, such first interconnection patterns may be exposed to a region on the top surface of the second interlayer insulating layer 234. For example, such first interconnection patterns may be the uppermost interconnection patterns of the first interconnection portion 232 provided in the second interlayer insulating layer 234. The first interconnection portion 232 may further include first connection contacts, which connect vertically-adjacent ones of the first interconnection patterns to each other, to connect the first interconnection patterns to the first semiconductor device 222, and to connect the first interconnection patterns to the first semiconductor substrate 210. The first connection contacts may be used for vertical interconnection. Some of the first connection contacts may vertically penetrate the second interlayer insulating layer 234 and the first interlayer insulating layer 224 and may be connected to the source, drain, and gate electrodes of the first transistors. Alternatively, at least one of the first connection contacts may be connected to various other elements of the first semiconductor device 222. In an embodiment, at least one of the first connection contacts may vertically penetrate the second interlayer insulating layer 234 and may be connected to adjacent ones of the first interconnection patterns. The first interconnection portion 232 may be formed of or may include metallic materials (e.g., copper (Cu) or tungsten (W)).

FIG. 2 illustrates an example, in which two first interconnection layers are provided in the first interconnection layer 230, but the inventive concept is not necessarily limited to this example. In an embodiment, one first interconnection layer or three or more first interconnection layers may be provided in the first interconnection layer 230. Hereinafter, the inventive concept will be further described with reference to the embodiment of FIG. 2.

The first interconnection layer 230 may further include a first protection layer 236 and first pads 238, which are provided on the top surface of the second interlayer insulating layer 234.

The first pads 238 may be disposed on the second interlayer insulating layer 234. The first pads 238 may be disposed on the top surface of the second interlayer insulating layer 234. The first pads 238 may be electrically connected to the first semiconductor device 222. For example, the first pads 238 on the top surface of the second interlayer insulating layer 234 may be coupled to some of the first interconnection patterns, as shown in FIG. 2. For example, at least one of the first interconnection patterns may be used as an under-pad pattern for the first pad 238. The first interconnection patterns may electrically connect the first semiconductor device 222 to the first pads 238. The first pads 238 may each have a plate shape and so may be substantially planar. In an embodiment, each of the first pads 238 may include a via portion and a pad portion, which are sequentially stacked and are connected to each other to form a single object, and may have a ‘T’-shaped cross-section. The first pads 238 may include a metallic material. As an example, the first pads 238 may be formed of or may include copper (Cu).

The first protection layer 236 on the top surface of the second interlayer insulating layer 234 may cover the first interconnection pattern of the first interconnection portion 232. The first protection layer 236 on the top surface of the second interlayer insulating layer 234 may enclose the first pads 238. The first pads 238 may be exposed to the outside of the first protection layer 236. For example, the first protection layer 236 may enclose the first pads 238, when viewed in a plan view, but might not veil the first pads 238. A top surface of the first protection layer 236 may be coplanar with top surfaces of the first pads 238. The first protection layer 236 may be formed of or may include silicon nitride (SiN), silicon oxide (SiO), silicon oxycarbide (SiOC), silicon oxynitride (SiON), and/or silicon carbonitride (SiCN).

The first vias 240 may vertically penetrate the first semiconductor substrate 210. In an embodiment, the first vias 240 may be used for vertical interconnection. The first vias 240 may vertically penetrate the first semiconductor substrate 210, the first interlayer insulating layer 224, and the second interlayer insulating layer 234 and may be coupled to a bottom surface of a portion of the first interconnection portion 232. The first vias 240 may vertically penetrate the first semiconductor substrate 210 and may be exposed to a region below the bottom surface of the first semiconductor substrate 210. The first vias 240 may include protruding portions that are extended to a region below the bottom surface of the first semiconductor substrate 210. Thus, the bottom surface of the first semiconductor substrate 210 may be spaced apart from the top surface of the redistribution substrate 100. Bottom surfaces of the first vias 240 may be in contact with the top surface of the redistribution substrate 100. Alternatively, unlike the illustrated structure, the bottom surface of the first vias 240 may be spaced apart from the top surface of the redistribution substrate 100. In an embodiment, the first vias 240 may be formed of or may include tungsten (W).

In an embodiment, the bottom surface of the first vias 240 may be coplanar with the bottom surface of the first semiconductor substrate 210. Additional pads may be provided on the bottom surface of the first semiconductor substrate 210, and the first vias 240 may be coupled to top surfaces of the pads. In an embodiment, the pads might not be provided. Hereinafter, the inventive concept will be further described with reference to the embodiment of FIGS. 1 and 2.

The first semiconductor chip 200 may be mounted on the redistribution substrate 100. For example, the redistribution conductive pattern 120 in the uppermost one of the substrate interconnection layers of the redistribution substrate 100 may penetrate the redistribution insulating layer 110 and may be coupled to the bottom surface of the first vias 240.

The dummy chip 300 may be disposed on the redistribution substrate 100. In the present specification, the “dummy chip” may mean a chip in which a transistor or an integrated circuit is not provided. The dummy chip 300 may have a front surface and a rear surface. The rear surface of the dummy chip 300 may face the redistribution substrate 100. For example, the dummy chip 300 may be disposed on the redistribution substrate 100 in a face-up manner. The dummy chip 300 may be horizontally spaced apart from the first semiconductor chip 200. A top surface of the dummy chip 300 may be located at the same level as a top surface of the first semiconductor chip 200.

The dummy chip 300 may include a second semiconductor substrate 310, a second interconnection layer 330, and second vias 340.

The second semiconductor substrate 310 may be provided. The second semiconductor substrate 310 may include a semiconductor material. For example, the second semiconductor substrate 310 may be a single-crystalline silicon substrate.

The second semiconductor substrate 310 may have a top surface and a bottom surface, which are opposite to each other. The top surface of the second semiconductor substrate 310 may be a front surface of the second semiconductor substrate 310, and the bottom surface may be a rear surface of the second semiconductor substrate 310. Here, the front surface of the second semiconductor substrate 310 may be defined as a surface of the second semiconductor substrate 310, on which interconnection lines or pads are formed, and the rear surface of the second semiconductor substrate 310 may defined as a surface that is opposite to the front surface. The rear surface of the second semiconductor substrate 310 may face the redistribution substrate 100.

The second interconnection layer 330 may be disposed on the second semiconductor substrate 310. The second interconnection layer 330 may be disposed on a top surface of the second semiconductor substrate 310. The second interconnection layer 330 may include a second interconnection portion 332 and a third interlayer insulating layer 334.

The top surface of the second semiconductor substrate 310 may be covered with the third interlayer insulating layer 334. A side surface of the third interlayer insulating layer 334 may be aligned to the side surface of the second semiconductor substrate 310. The third interlayer insulating layer 334 may be formed of or may include silicon oxide (SiO), silicon nitride (SiN), and/or silicon oxynitride (SiON). Alternatively, the third interlayer insulating layer 334 may include a low-k dielectric material. The third interlayer insulating layer 334 may have a mono- or multi-layered structure. In the case where the third interlayer insulating layer 334 has the multi-layered structure, each of second interconnection layers, which will be described below, may be provided in a single insulating layer, and etch stop layers may be interposed between the insulating layers. For example, the etch stop layers may be provided on bottom surfaces of the insulating layers. The etch stop layer may be formed of or may include silicon nitride (SiN), silicon oxynitride (SiON), and/or silicon carbonitride (SiCN).

The second interconnection portion 332 may include second interconnection patterns, which are buried in the third interlayer insulating layer 334. In an embodiment, the second interconnection patterns may be used for horizontal interconnection. As an example, the second interconnection patterns, which are placed at the same vertical level, may constitute a single second interconnection layer. The second interconnection patterns may be positioned between top and bottom surfaces of the third interlayer insulating layer 334. Some of the second interconnection patterns may be disposed in an upper portion of the third interlayer insulating layer 334. For example, at least one of the second interconnection patterns may be exposed to a region on the top surface of the third interlayer insulating layer 334. For example, such second interconnection patterns may be the uppermost interconnection patterns of the second interconnection portion 332 provided in the third interlayer insulating layer 334. The second interconnection portion 332 may further include second connection contacts, which connect vertically-adjacent ones of the second interconnection patterns to each other. The second connection contacts may be used for vertical interconnection. The second connection contacts may vertically penetrate the third interlayer insulating layer 334 and may be connected to adjacent ones of the second interconnection patterns. In an embodiment, the second interconnection portion 332 may be formed of or may include metallic materials (e.g., copper (Cu) or tungsten (W)).

FIG. 2 illustrates an example, in which two second interconnection layers are provided in the second interconnection layer 330, but the inventive concept is not necessarily limited to this example. In an embodiment, one second interconnection layer or three or more second interconnection layers may be provided in the second interconnection layer 330. Hereinafter, the inventive concept will be further described with reference to the embodiment of FIG. 2.

The second interconnection layer 330 may further include a second protection layer 336 and second pads 338, which are provided on the top surface of the third interlayer insulating layer 334.

The second pads 338 may be disposed on the third interlayer insulating layer 334. The second pads 338 may be disposed on the top surface of the third interlayer insulating layer 334. As shown in FIG. 2, the second pads 338 on the top surface of the third interlayer insulating layer 334 may be coupled to some of the second interconnection patterns. For example, at least one of the second interconnection patterns may be used as an under-pad pattern for the second pad 338. The second pads 338 may have a plate shape. In an embodiment, the second pads 338 may include a via portion and a pad portion, which are sequentially stacked and are connected to each other to form a single object, and may have a ‘T’-shaped cross-section. The second pads 338 may include a metallic material. In an embodiment, the second pads 338 may be formed of or may include copper (Cu).

The second protection layer 336 on the top surface of the third interlayer insulating layer 334 may cover the second interconnection pattern of the second interconnection portion 332. The second protection layer 336 on the top surface of the third interlayer insulating layer 334 may enclose the second pads 338. The second pads 338 may be exposed to the outside of the second protection layer 336. For example, the second protection layer 336 may enclose the second pads 338, when viewed in a plan view, but might not veil the second pads 338. A top surface of the second protection layer 336 may be coplanar with top surfaces of the second pads 338. The second protection layer 336 may be formed of or may include silicon nitride (SiN), silicon oxide (SiO), silicon oxycarbide (SiOC), silicon oxynitride (SiON), and/or silicon carbonitride (SiCN).

The second vias 340 may vertically penetrate the second semiconductor substrate 310. In an embodiment, the second vias 340 may be used for vertical interconnection. The second vias 340 may vertically penetrate the second semiconductor substrate 310 and the third interlayer insulating layer 334 and may be coupled to a bottom surface of a portion of the second interconnection portion 332. The second vias 340 may vertically penetrate the second semiconductor substrate 310 and may be exposed to a region below the bottom surface of the second semiconductor substrate 310. The second vias 340 may include protruding portions that are extended to a region below the bottom surface of the second semiconductor substrate 310. Thus, the bottom surface of the second semiconductor substrate 310 may be spaced apart from the top surface of the redistribution substrate 100. Bottom surfaces of the second vias 340 may be in contact with the top surface of the redistribution substrate 100. Alternatively, the bottom surface of the second vias 340 may be spaced apart from the top surface of the redistribution substrate 100. The second vias 340 may be formed of or may include tungsten (W).

A second width W2 of the second vias 340 may be larger than a first width W1 of the first vias 240. As an example, the second width W2 of the second vias 340 may be 5 to 50 times larger than the first width W1 of the first vias 240. The second width W2 of the second vias 340 may range from 10 μm to 100 μm. The first width W1 of the first vias 240 may range from 0.2 μm to 2 μm.

In an embodiment, the bottom surface of the second vias 340 may be coplanar with the bottom surface of the second semiconductor substrate 310. Additional pads may be provided on the bottom surface of the second semiconductor substrate 310, and the second vias 340 may be coupled to top surfaces of the pads. In an embodiment, the pads might not be provided. Hereinafter, the inventive concept will be further described with reference to the embodiment of FIGS. 1 and 2.

The dummy chip 300 may be mounted on the redistribution substrate 100. For example, the redistribution conductive pattern 120 in the uppermost one of the substrate interconnection layers of the redistribution substrate 100 may penetrate the redistribution insulating layer 110 and may be coupled to the bottom surface of the second vias 340.

A mold layer 400 may be provided on the redistribution substrate 100. The mold layer 400 on the redistribution substrate 100 may enclose the first semiconductor chip 200 and the dummy chip 300. The first semiconductor chip 200 and the dummy chip 300 might not be covered with the mold layer 400 and may be exposed to a region on a top surface of the mold layer 400. The top surface of the mold layer 400, the top surface of the first semiconductor chip 200, and the top surface of the dummy chip 300 may be substantially flat and may be substantially coplanar with each other. Since the first semiconductor substrate 210 of the first semiconductor chip 200 and the second semiconductor substrate 310 of the dummy chip 300 are spaced apart from the redistribution substrate 100, the mold layer 400 may cover the bottom surface of the first semiconductor substrate 210 and the bottom surface of the dummy chip 300. Below the first semiconductor chip 200 and the dummy chip 300, the mold layer 400 may fill a space between the redistribution substrate 100 and the first semiconductor substrate 210 and may also a space between the redistribution substrate 100 and the second semiconductor substrate 310 and may enclose the first vias 240 and the second vias 340. The first vias 240 and the second vias 340 may be exposed to a region below a bottom surface of the mold layer 400. The mold layer 400 may be in contact with the top surface of the redistribution substrate 100. The bottom surface of the mold layer 400 may be substantially flat, depending on the shape of the top surface of the redistribution substrate 100. The mold layer 400 may include an insulating material. For example, the mold layer 400 may be formed of or may include an insulating polymer material (e.g., an epoxy molding compound (EMC)).

The conductive posts 450 may be provided on the redistribution substrate 100. For example, the conductive posts 450 may be horizontally spaced apart from the first semiconductor chip 200 and the dummy chip 300. Each of the conductive posts 450 may be a part of a vertical connection structure that is used to connect a second semiconductor chip 500, which will be described below, to the redistribution substrate 100. Each of the conductive posts 450 may be a pillar-shaped pattern. The conductive posts 450 may vertically penetrate the mold layer 400. For example, the conductive posts 450 may be extended toward the top surface of the mold layer 400 and may be exposed to a region on the top surface of the mold layer 400. The top surface of the mold layer 400, the top surface of the first semiconductor chip 200, the top surface of the dummy chip 300, and the top surface of the conductive posts 450 may be substantially flat and may be substantially coplanar with each other. The conductive posts 450 may be extended toward the bottom surface of the mold layer 400 and may be coupled to the redistribution conductive patterns 120 of the redistribution substrate 100. For example, the redistribution conductive pattern 120 in the uppermost one of the substrate interconnection layers of the redistribution substrate 100 may penetrate the redistribution insulating layer 110 and may be coupled to the bottom surface of the conductive posts 450. The conductive posts 450 may include a conductive material. For example, the conductive posts 450 may be formed of or may include metallic materials (e.g., copper (Cu) or tungsten (W)).

A third width W3 of the conductive posts 450 may be larger than the first width W1 of the first vias 240. In an embodiment, the third width W3 of the conductive posts 450 may be 5 to 50 times larger than the first width W1 of the first vias 240. The third width W3 of the conductive posts 450 may be substantially equal to or similar to the second width W2 of the second vias 340. Alternatively, the second width W2 of the second vias 340 may be substantially equal to or larger than the third width W3 of the conductive posts 450. The third width W3 of the conductive posts 450 may range from 10 μm to 100 μm.

A seed layer 452 may enclose an outer side surface of each of the conductive posts 450. The seed layers 452 may cover the outer side surfaces and the top surfaces of the conductive posts 450. Alternatively, the seed layers 452 may cover the outer side surfaces and the bottom surfaces of the conductive posts 450. In an embodiment, the seed layers 452 might not be provided. The seed layers 452 may be formed of or may include metallic materials (e.g., gold (Au) or nickel (Ni)).

In an embodiment, the bottom surface of the mold layer 400 may be flat. For example, the mold layer 400 may have a constant thickness below the first semiconductor chip 200 and the dummy chip 300. For example, the mold layer 400 of the constant thickness may be provided below the first semiconductor chip 200 and the dummy chip 300, and the bottom surface of the mold layer 400 may be flat below the first semiconductor chip 200 and the dummy chip 300. Thus, the top surface of the redistribution substrate 100, which is provided below the mold layer 400, may be flat, and the substrate interconnection layers in the redistribution substrate 100 may also be flat. This may make it possible to increase the structural stability of the semiconductor package. This will be described in more detail with reference to a fabrication method below.

The second semiconductor chip 500 may be provided on the mold layer 400, the first semiconductor chip 200, and the dummy chip 300. The second semiconductor chip 500 may have a front surface and a rear surface. The second semiconductor chip 500 may be provided such that the front surface thereof faces the redistribution substrate 100. For example, the second semiconductor chip 500 may be disposed on the mold layer 400, the first semiconductor chip 200, and the dummy chip 300 in a face-down manner. For example, the front surface of the second semiconductor chip 500 may face the front surface of the first semiconductor chip 200 and the front surface of the dummy chip 300. A side surface of the second semiconductor chip 500 may be aligned to a side surface of the mold layer 400. The first semiconductor chip 200 and the dummy chip 300 may be fully overlapped with the second semiconductor chip 500, when viewed in a plan view. For example, the second semiconductor chip 500 may cover all of the mold layer 400, the first semiconductor chip 200, and the dummy chip 300. The second semiconductor chip 500 may be in contact with the top surface of the mold layer 400, the top surface of the first semiconductor chip 200, and the top surface of the dummy chip 300.

The second semiconductor chip 500 may include a third semiconductor substrate 510, a second circuit layer 520, and a third interconnection layer 530.

The third semiconductor substrate 510 may be provided. The third semiconductor substrate 510 may include a semiconductor material. For example, the third semiconductor substrate 510 may be a single-crystalline silicon substrate.

The third semiconductor substrate 510 may have a top surface and a bottom surface, which are opposite to each other. The bottom surface of the third semiconductor substrate 510 may be a front surface of the third semiconductor substrate 510, and the top surface may be a rear surface of the third semiconductor substrate 510. Here, the front surface of the third semiconductor substrate 510 may be defined as a surface of the third semiconductor substrate 510, on which semiconductor devices, interconnection lines, or pads are formed or provided, and the rear surface of the third semiconductor substrate 510 may be defined as a surface that is opposite to the front surface. The front surface of the third semiconductor substrate 510 may face the mold layer 400, the first semiconductor chip 200, and the dummy chip 300.

The second circuit layer 520 may be disposed on the third semiconductor substrate 510. The second circuit layer 520 may be disposed on the bottom surface of the third semiconductor substrate 510. The second circuit layer 520 may include a second semiconductor device 522 and a fourth interlayer insulating layer 524.

The second semiconductor device 522 may include second transistors, which are formed or provided on the top surface of the third semiconductor substrate 510. In an embodiment, each of the second transistors may include source and drain regions, which are formed in an upper portion of the third semiconductor substrate 510, a gate electrode, which is provided on the top surface of the third semiconductor substrate 510, and a gate insulating layer interposed between the third semiconductor substrate 510 and the gate electrode. FIG. 2 illustrates an example, in which five second transistors are provided, but the inventive concept is not necessarily limited to this example. For example, the second semiconductor device 522 may include a plurality of second transistors. The second semiconductor device 522 may include a logic circuit. The second semiconductor device 522 may include a shallow device isolation pattern, which is provided in the third semiconductor substrate 510, and may be used as a part of a logic cell. For example, the second semiconductor chip 500 may be a logic chip. The second semiconductor device 522 may include a memory circuit. As an example, the second semiconductor chip 500 may be a memory chip. Alternatively, the second semiconductor device 522 may include a passive device (e.g., a capacitor).

The bottom surface of the third semiconductor substrate 510 may be covered with the fourth interlayer insulating layer 524. The second semiconductor device 522 may be buried in the fourth interlayer insulating layer 524 below the bottom surface of the third semiconductor substrate 510. Here, the fourth interlayer insulating layer 524 may be provided below the second semiconductor device 522 to cover the second semiconductor device 522. In an embodiment, the second semiconductor device 522 might not be exposed to the outside of the fourth interlayer insulating layer 524. A side surface of the fourth interlayer insulating layer 524 may be aligned to a side surface of the third semiconductor substrate 510. The fourth interlayer insulating layer 524 may be formed of or may include silicon oxide (SiO), silicon nitride (SiN), and/or silicon oxynitride (SiON). Alternatively, the fourth interlayer insulating layer 524 may include a low-k dielectric material. The fourth interlayer insulating layer 524 may have a mono- or multi-layered structure.

The third interconnection layer 530 may be disposed on the second circuit layer 520. The third interconnection layer 530 may be disposed on a bottom surface of the second circuit layer 520. The third interconnection layer 530 may include a third interconnection portion 532 and a fifth interlayer insulating layer 534.

A bottom surface of the fourth interlayer insulating layer 524 may be covered with the fifth interlayer insulating layer 534. A side surface of the fifth interlayer insulating layer 534 may be aligned to the side surface of the third semiconductor substrate 510. The fifth interlayer insulating layer 534 may be formed of or may include silicon oxide (SiO), silicon nitride (SiN), and/or silicon oxynitride (SiON). Alternatively, the fifth interlayer insulating layer 534 may include a low-k dielectric material. The fifth interlayer insulating layer 534 may have a mono- or multi-layered structure. In the case where the fifth interlayer insulating layer 534 has the multi-layered structure, each of third interconnection layers, which will be described below, may be provided in a single insulating layer, and an etch stop layer may be interposed between the insulating layers. For example, the etch stop layer may be provided on bottom surfaces of the insulating layers. The etch stop layer may be formed of or may include silicon nitride (SiN), silicon oxynitride (SiON), and/or silicon carbonitride (SiCN).

The third interconnection portion 532 may include third interconnection patterns buried in the fifth interlayer insulating layer 534. The third interconnection patterns may be used for horizontal interconnection. As an example, the third interconnection patterns, which are placed at the same vertical level, may constitute a single third interconnection layer. The third interconnection patterns may be positioned between top and bottom surfaces of the fifth interlayer insulating layer 534. Some of the third interconnection patterns may be disposed below the fifth interlayer insulating layer 534. For example, some of the third interconnection patterns may be exposed to a region below the bottom surface of the fifth interlayer insulating layer 534. For example, such third interconnection patterns may be the lowermost interconnection patterns of the third interconnection portion 532 provided in the fifth interlayer insulating layer 534. The third interconnection portion 532 may further include third connection contacts, which connect vertically-adjacent ones of the third interconnection patterns to each other, to connect the third interconnection patterns to the second semiconductor device 522, and to connect the third interconnection patterns to the third semiconductor substrate 510. The third connection contacts may be used for vertical interconnection. The third connection contacts may vertically penetrate the fifth interlayer insulating layer 534 and the fourth interlayer insulating layer 524 and may be connected to the source, drain, and gate electrodes of the second transistors. Alternatively, at least one of the third connection contacts may be connected to various other elements of the second semiconductor device 522. In an embodiment, at least one of the third connection contacts may vertically penetrate the fifth interlayer insulating layer 534 and may be connected to adjacent ones of the third interconnection patterns. The third interconnection portion 532 may be formed of or may include metallic materials (e.g., copper (Cu) or tungsten (W)).

FIG. 2 illustrates an example, in which two third interconnection layers are provided in the third interconnection layer 530, but the inventive concept is not necessarily limited to this example. In an embodiment, one third interconnection layer or three or more third interconnection layers may be provided in the third interconnection layer 530. Hereinafter, the inventive concept will be further described with reference to the embodiment of FIG. 2.

The third interconnection layer 530 may further include a third protection layer 536 and third pads 538, which are provided on the bottom surface of the fifth interlayer insulating layer 534.

The third pads 538 may be disposed on the fifth interlayer insulating layer 534. The third pads 538 may be disposed on the bottom surface of the fifth interlayer insulating layer 534. The third pads 538 may be electrically connected to the second semiconductor device 522. For example, as shown in FIG. 2, the third pads 538 on the bottom surface of the fifth interlayer insulating layer 534 may be coupled to some of the third interconnection patterns. For example, at least one of the third interconnection patterns may be used as an under-pad pattern for the third pad 538. The third interconnection patterns may electrically connect the second semiconductor device 522 to the third pads 538. The third pads 538 may have a plate shape. In an embodiment, the third pads 538 may include a pad portion and a via portion, which are sequentially stacked and are connected to each other to form a single object, and may have a cross-section shaped like an inverted letter ‘T’. The third pads 538 may include a metal material. In an embodiment, the third pads 538 may be formed of or may include copper (Cu).

The third protection layer 536 on the bottom surface of the fifth interlayer insulating layer 534 may cover the third interconnection pattern of the third interconnection portion 532. The third protection layer 536 on the bottom surface of the fifth interlayer insulating layer 534 may enclose the third pads 538. The third pads 538 may be exposed to the outside of the third protection layer 536. For example, the third protection layer 536 may enclose the third pads 538, when viewed in a plan view, but might not veil the third pads 538. A top surface of the third protection layer 536 may be coplanar with a top surface of the third pads 538. The third protection layer 536 may be formed of or may include silicon nitride (SiN), silicon oxide (SiO), silicon oxycarbide (SiOC), silicon oxynitride (SiON), and/or silicon carbonitride (SiCN).

FIG. 1 illustrates an example, in which the second semiconductor chip 500 does not include an additional via, but the inventive concept is not necessarily limited to this example. The second semiconductor chip 500 may include vias, which vertically penetrate the third semiconductor substrate 510 and are connected to the second circuit layer 520 or the third interconnection layer 530. Hereinafter, the inventive concept will be further described with reference to the embodiment of FIG. 1.

The second semiconductor chip 500 may be mounted on the first semiconductor chip 200, the dummy chip 300, and the conductive posts 450.

The second semiconductor chip 500 may be disposed on the mold layer 400. The third pads 538 of the second semiconductor chip 500 may be vertically aligned to the first pads 238 of the first semiconductor chip 200, the second pads 338 of the dummy chip 300, and the conductive posts 450. The second semiconductor chip 500 may be in contact with the first semiconductor chip 200, the dummy chip 300, and the conductive posts 450.

The first semiconductor chip 200 and the second semiconductor chip 500 may be connected to each other. For example, the first semiconductor chip 200 and the second semiconductor chip 500 may be in contact with each other. At an interface between the first semiconductor chip 200 and the second semiconductor chip 500, the first pads 238 of the first semiconductor chip 200 may be bonded to the third pads 538 of the second semiconductor chip 500. Here, the first pads 238 and the third pads 538 may form an inter-metal hybrid bonding structure. In the present specification, the hybrid bonding structure may mean a bonding structure which is formed by two materials, which are of the same kind and are fused at an interface therebetween. For example, the first pads 238 and the third pads 538, which are bonded to each other, may have a continuous structure, and there may be no visible interface between the first pads 238 and the third pads 538. For example, the first pad 238 and the third pad 538 may be formed of the same material, and in this case, there may be no interface between the first pad 238 and the third pad 538. For example, the first pad 238 and the third pad 538 may be provided in the form of a single object. For example, the first pad 238 and the third pad 538 may be bonded to form a single object.

At the interface between the first semiconductor chip 200 and the second semiconductor chip 500, the first protection layer 236 of the first semiconductor chip 200 may be bonded to the third protection layer 536 of the second semiconductor chip 500. Here, the first protection layer 236 and the third protection layer 536 may form a hybrid bonding structure of oxide, nitride, or oxynitride. For example, the first protection layer 236 and the third protection layer 536, which are bonded to each other, may have a continuous structure, and there may be no visible interface between the first protection layer 236 and the third protection layer 536. For example, the first protection layer 236 and the third protection layer 536 may be formed of the same material, and in this case, there may be no visible interface between the first protection layer 236 and the third protection layer 536. For example, the first protection layer 236 and the third protection layer 536 may be provided in the form of a single object. For example, the first protection layer 236 and the third protection layer 536 may be bonded to form a single object. However, the inventive concept is not necessarily limited to this example. The first protection layer 236 and the third protection layer 536 may be formed of different materials. The first protection layer 236 and the third protection layer 536 might not have a continuous structure, and there may be a visible interface between the first protection layer 236 and the third protection layer 536.

The dummy chip 300 and the second semiconductor chip 500 may be connected to each other. For example, the dummy chip 300 and the second semiconductor chip 500 may be in contact with each other. At an interface between the dummy chip 300 and the second semiconductor chip 500, the second pads 338 of the dummy chip 300 may be bonded to the third pads 538 of the second semiconductor chip 500. Here, the second pads 338 and the third pads 538 may form an inter-metal hybrid bonding structure. For example, the second pads 338 and the third pads 538, which are bonded to each other, may have a continuous structure, and there may be no visible interface between the second pads 338 and the third pads 538. For example, the second pads 338 and the third pads 538 may be bonded to form a single object.

At the interface between the dummy chip 300 and the second semiconductor chip 500, the second protection layer 336 of the dummy chip 300 may be bonded to the third protection layer 536 of the second semiconductor chip 500. Here, the second protection layer 336 and the third protection layer 536 may form a hybrid bonding structure of oxide, nitride, or oxynitride. For example, the second protection layer 336 and the third protection layer 536, which are bonded to each other, may have a continuous structure, and there may be no visible interface between the second protection layer 336 and the third protection layer 536. For example, the second protection layer 336 and the third protection layer 536 may be bonded to form a single object. However, the inventive concept is not necessarily limited to this example. The second protection layer 336 and the third protection layer 536 might not have a continuous structure, and there may be a visible interface between the second protection layer 336 and the third protection layer 536.

The conductive posts 450 may be coupled to bottom surfaces of the third pads 538 of the second semiconductor chip 500. For example, the second semiconductor chip 500 may be electrically connected to the conductive posts 450.

The second semiconductor chip 500 may be electrically connected to the first semiconductor chip 200. In an embodiment, the front surface of the first semiconductor chip 200 may face the front surface of the second semiconductor chip 500, and the front surface of the first semiconductor chip 200 may be directly connected to the front surface of the second semiconductor chip 500. Thus, a length of an electric connection path between the first semiconductor chip 200 and the second semiconductor chip 500 may be shortened.

The second semiconductor chip 500 may be electrically connected to the redistribution substrate 100 through the dummy chip 300. The dummy chip 300 may be configured to deliver operation signals, which are applied through the redistribution substrate 100, to the second semiconductor chip 500. The second semiconductor chip 500 may be electrically connected to the redistribution substrate 100 through the conductive posts 450. The conductive posts 450 may be configured to deliver power/ground signals, which are applied through the redistribution substrate 100, to the second semiconductor chip 500.

According to an embodiment of the inventive concept, the dummy chip 300, which directly connects the second semiconductor chip 500 to the redistribution substrate 100, may include the second vias 340 of a large width (e.g., the second width W2). For example, the second width W2 of the second vias 340 may be larger than the first width W1 of the first vias 240 of the first semiconductor chip 200, which include the integrated circuits. Thus, an interconnection structure in the dummy chip 300 may have a reduced electrical resistance, and this may make it possible to reduce an electrical resistance of an electric path between the second semiconductor chip 500 and the redistribution substrate 100. Furthermore, an electrical resistance of an electric path between the second semiconductor chip 500 and the redistribution substrate 100 passing through the dummy chip 300 may be smaller than an electrical resistance of an electric path between the second semiconductor chip 500 and the redistribution substrate 100 passing through the first semiconductor chip 200. For example, a semiconductor package with enhanced electrical characteristics may be provided.

Furthermore, in a region where it is difficult to provide the dummy chip 300 in the form of a chip, the conductive posts 450 may have a third width W3 larger than the first width W1 of the first vias 240. An electrical resistance of an electric path between the second semiconductor chip 500 and the redistribution substrate 100 passing through the conductive posts 450 may be smaller than an electrical resistance of an electric path between the second semiconductor chip 500 and the redistribution substrate 100 passing through the first semiconductor chip 200. For example, an electric path between the second semiconductor chip 500 and the redistribution substrate 100 may have a sufficiently low electrical resistance in all regions except for the region containing the first semiconductor chip 200 with integrated circuits, and this may make it possible to realize a semiconductor package with enhanced electrical characteristics.

In the description of the embodiments to be explained below, to the extent that an element is not described in detail, it may be understood that the element is at least similar to a corresponding element that has been described elsewhere within the present disclosure.

FIG. 4 is a cross-sectional view illustrating a semiconductor package according to an embodiment of the inventive concept.

Referring to FIG. 4, the redistribution substrate 100 might not be provided. For example, the bottom surface of the mold layer 400 might not be covered with any other element. Bottom surfaces of the first vias 240 of the first semiconductor chip 200, bottom surfaces of the second vias 340 of the dummy chip 300, and bottom surfaces of the conductive posts 450 may be exposed to a region below the bottom surface of the mold layer 400.

The outer terminals 130 may be provided on the exposed bottom surface of the first vias 240, the exposed bottom surface of the second vias 340, and the exposed bottom surface of the conductive posts 450.

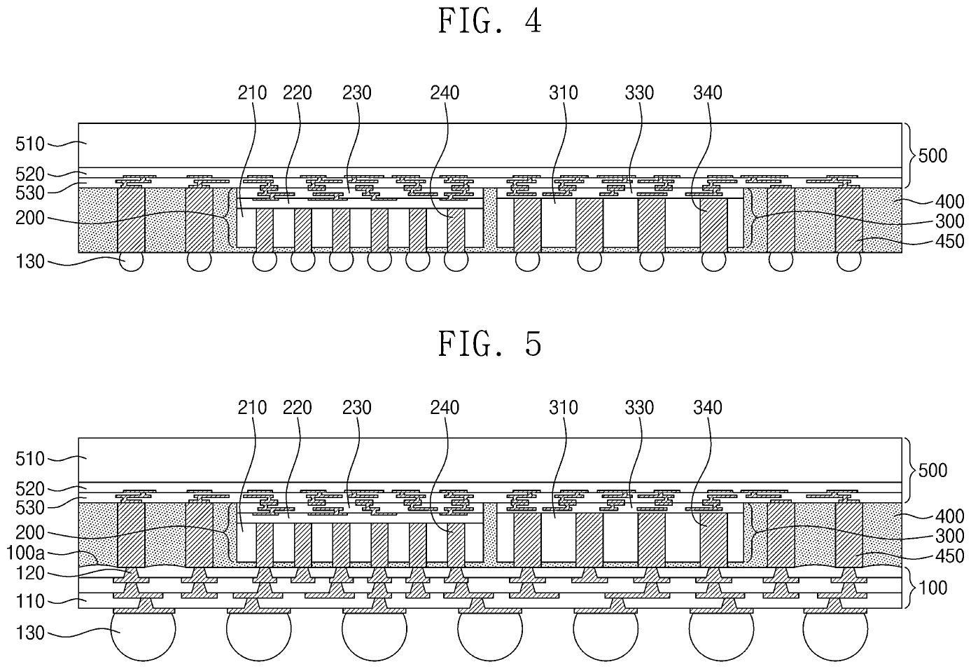

FIG. 5 is a cross-sectional view illustrating a semiconductor package according to an embodiment of the inventive concept.

Referring to FIG. 5, at least a portion of the bottom surface of the mold layer 400 might not be flat. For example, the bottom surface of the mold layer 400 below the first semiconductor chip 200 and the dummy chip 300 may be flat, and the bottom surface of the mold layer 400 beside the first semiconductor chip 200 and the dummy chip 300 may include a concave portion. In an embodiment, the bottom surface of the mold layer 400 may be concave between the conductive posts 450 and between the conductive posts 450 and the side surface of the mold layer 400. Here, the expression ‘the bottom surface of the mold layer 400 is concave’ may mean that the bottom surface of the mold layer 400 is recessed toward the top surface of the mold layer 400.

At least a portion of the top surface of the redistribution substrate 100 might not be flat owing to the shape of the bottom surface of the mold layer 400. For example, the top surface of the redistribution substrate 100 below the first semiconductor chip 200 and the dummy chip 300 may be flat, and the redistribution substrate 100 beside the first semiconductor chip 200 and the dummy chip 300 may have a convex top surface 100a. In an embodiment, the top surface 100a of the redistribution substrate 100 may have a convex shape between the conductive posts 450 and between the conductive posts 450 and the side surface of the mold layer 400. Here, the expression ‘the top surface 100a of the redistribution substrate 100 is convex’ may mean that the top surface of the redistribution substrate 100 has a protruding shape in an upward direction.

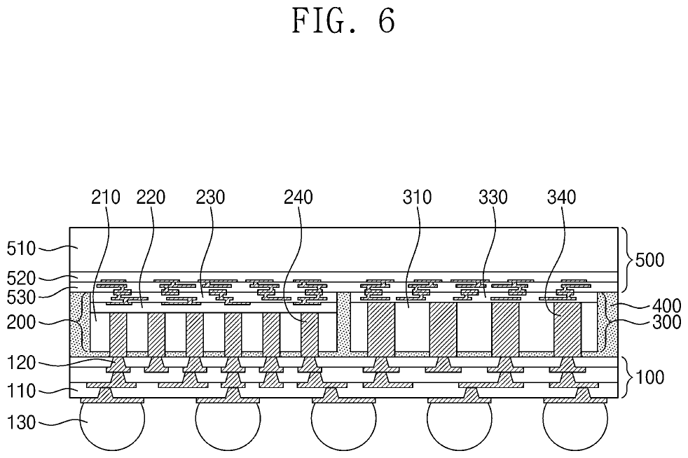

FIG. 6 is a cross-sectional view illustrating a semiconductor package according to an embodiment of the inventive concept.

Referring to FIG. 6, the semiconductor package might not include the conductive posts 450 (e.g., see FIG. 1). The first semiconductor chip 200 and the dummy chip 300 may be disposed on the redistribution substrate 100. The first semiconductor chip 200 and the dummy chip 300 may be disposed on the redistribution substrate 100 in a face-up manner. The second semiconductor chip 500 may be disposed on the first semiconductor chip 200 and the dummy chip 300. The second semiconductor chip 500 may be disposed on the first semiconductor chip 200 and the dummy chip 300 in a face-down manner. The second semiconductor chip 500 may be bonded to the first semiconductor chip 200 and the dummy chip 300. The second semiconductor chip 500 may be electrically connected to the first semiconductor chip 200 and may be electrically connected to the redistribution substrate 100 through the dummy chip 300. Between the redistribution substrate 100 and the second semiconductor chip 500, the mold layer 400 may enclose the first semiconductor chip 200 and the dummy chip 300.

In an embodiment, the front surface of the first semiconductor chip 200 may face the front surface of the second semiconductor chip 500, and the front surface of the first semiconductor chip 200 may be directly connected to the front surface of the second semiconductor chip 500. Thus, a length of an electric connection path between the first semiconductor chip 200 and the second semiconductor chip 500 may be shortened. In addition, since the second vias 340 of the dummy chip 300 connecting the redistribution substrate 100 to the second semiconductor chip 500 have a large thickness, an electrical resistance of an electric connection between the redistribution substrate 100 and the second semiconductor chip 500 may be reduced. For example, a semiconductor package with enhanced electrical characteristics may be provided.

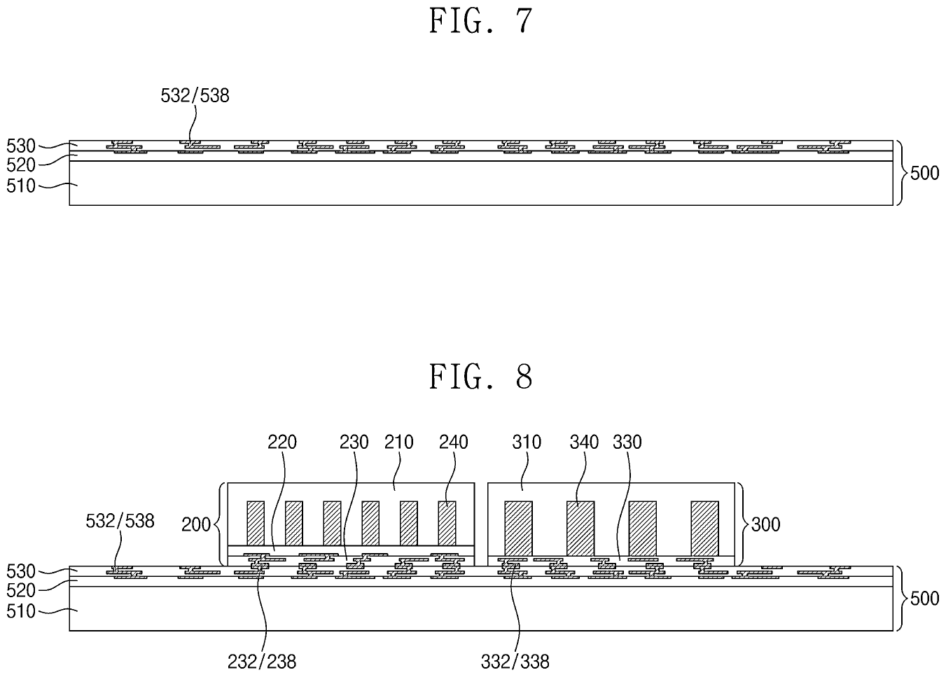

FIGS. 7 to 12 are cross-sectional views illustrating a method of fabricating a semiconductor package, according to an embodiment of the inventive concept.

Referring to FIG. 7, the second semiconductor chip 500 may be provided. The second semiconductor chip 500 may be substantially the same as the second semiconductor chip 500 described with reference to FIGS. 1 to 6. For example, the second semiconductor chip 500 may include the third semiconductor substrate 510, the second circuit layer 520 provided on the third semiconductor substrate 510, and the third interconnection layer 530 provided on the second circuit layer 520. The third interconnection layer 530 may include the third interconnection portion 532, which is connected to the integrated circuit in the second circuit layer 520, and the third pads 538, which are exposed to a region on the top surface of the third interconnection layer 530.

Referring to FIG. 8, the first semiconductor chip 200 may be provided. The first semiconductor chip 200 may be substantially the same as the first semiconductor chip 200 described with reference to FIGS. 1 to 6. For example, the first semiconductor chip 200 may include the first semiconductor substrate 210, the first circuit layer 220, which is provided on the first semiconductor substrate 210, the first interconnection layer 230, which is provided on the first circuit layer 220, and the first vias 240, which penetrate the first semiconductor substrate 210 and are connected to the first interconnection layer 230 or the first circuit layer 220. The first interconnection layer 230 may include the first interconnection portion 232, which is connected to the integrated circuit in the first circuit layer 220, and the first pads 238, which are exposed to a region on a surface of the first interconnection layer 230. The first vias 240 might not be exposed to a region on a surface of the first semiconductor substrate 210, which is opposite to the first circuit layer 220. For example, the first vias 240 may be placed in the first semiconductor substrate 210.

The dummy chip 300 may be provided. The dummy chip 300 may be substantially the same as the dummy chip 300 described with reference to FIGS. 1 to 6. For example, the dummy chip 300 may include the second semiconductor substrate 310, the second interconnection layer 330 provided on the second semiconductor substrate 310, and the second vias 340, which penetrate the second semiconductor substrate 310 and are connected to the second interconnection layer 330. The second interconnection layer 330 may include the second interconnection portion 332, which is provided in the second interconnection layer 330, and the second pads 338, which are exposed to a region on a surface of the second interconnection layer 330. The second vias 340 might not be exposed to a region on a surface of the second semiconductor substrate 310, which is opposite to the second interconnection layer 330. For example, the second vias 340 may be placed in the second semiconductor substrate 310.

The first semiconductor chip 200 and the dummy chip 300 may be mounted on the second semiconductor chip 500. The first semiconductor chip 200 and the dummy chip 300 may be aligned to the second semiconductor chip 500 such that the first pads 238 of the first semiconductor chip 200 and the second pads 338 of the dummy chip 300 are placed on the third pads 538 of the second semiconductor chip 500. A thermal treatment process may be performed on the first semiconductor chip 200 and the dummy chip 300. As a result of the thermal treatment process, the first and second pads 238 and 338 may be bonded to the third pads 538. For example, the first or second pad 238 or 338 and the third pad 538 may be bonded to form a single object. The bonding of the first and second pads 238 and 338 and the third pads 538 may be achieved in a natural manner. For example, the first and second pads 238 and 338 and the third pads 538 may be formed of the same material (e.g., copper (Cu)), and in this case, the first and second pads 238 and 338 and the third pads 538 may be bonded to each other by an intermetal hybrid bonding process, which is caused by a surface activation at an interface between the first and second pads 238 and 338 and the third pads 538 in contact with each other. The first and second pads 238 and 338 and the third pads 538 may be bonded to each other by the thermal treatment process.

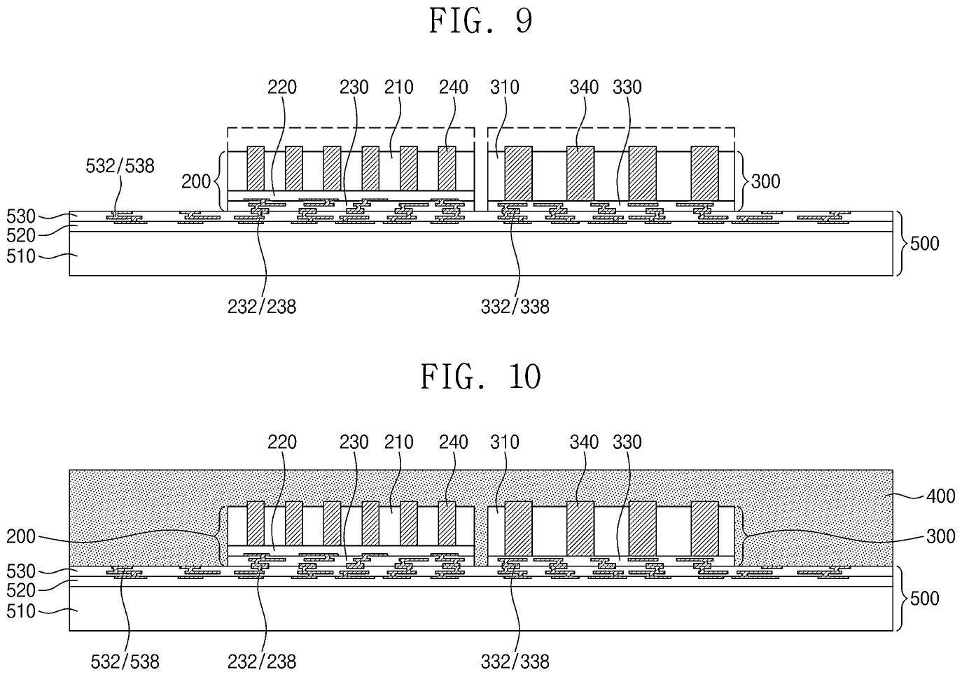

Referring to FIG. 9, the first semiconductor substrate 210 and the second semiconductor substrate 310 may be partially removed. For example, a grinding process or a chemical-mechanical polishing (CMP) process may be performed on the top surface of the first semiconductor chip 200 and the top surface of the dummy chip 300. The grinding process or the chemical-mechanical polishing process may be performed to expose the first vias 240 and the second vias 340. Thus, a portion of the first semiconductor substrate 210, which is located on top surfaces of the first vias 240, and a portion of the second semiconductor substrate 310, which is located on the top surfaces of the second vias 340, may be removed. The grinding process or the chemical-mechanical polishing process may be further performed after the top surfaces of the first vias 240 and the top surfaces of the second vias 340 are exposed to the outside. Thus, the top surface of the first semiconductor substrate 210 may be lowered to a level lower than the top surfaces of the first vias 240, and the top surface of the second semiconductor substrate 310 may be lowered to a level lower than the top surfaces of the second vias 340.

Referring to FIG. 10, the mold layer 400 may be formed on the second semiconductor chip 500. For example, the mold layer 400 may be formed by forming an insulating material on the second semiconductor chip 500 and curing the insulating material. The mold layer 400 on the second semiconductor chip 500 may cover the first semiconductor chip 200 and the dummy chip 300.

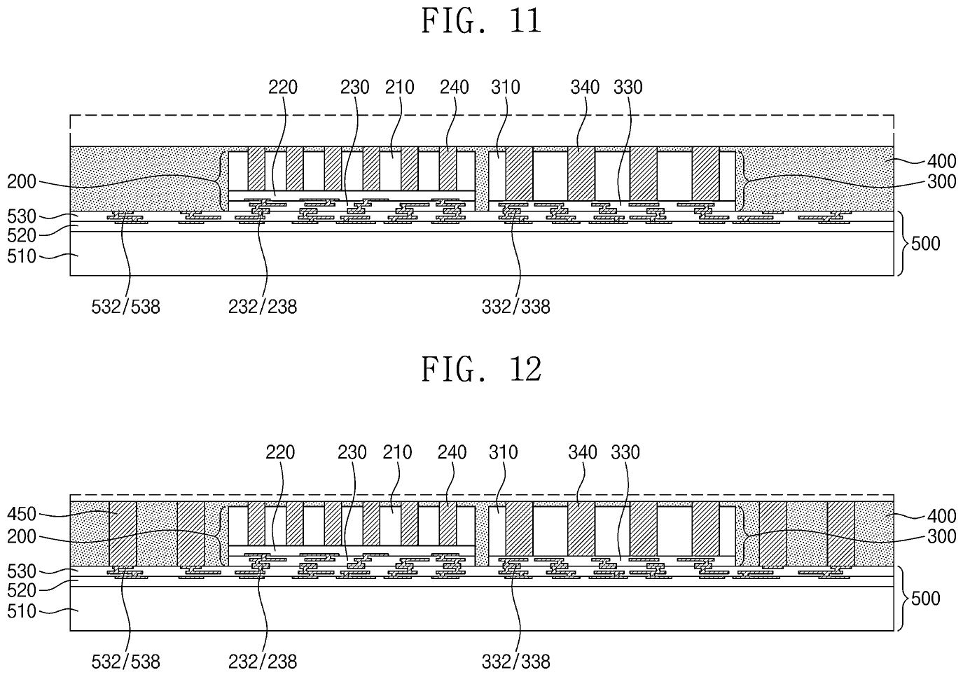

Referring to FIG. 11, a portion of the mold layer 400 may be removed. For example, a grinding process or a chemical-mechanical polishing (CMP) process may be performed on the top surface of the mold layer 400. The grinding process or the chemical-mechanical polishing process may be performed to expose the first vias 240 and the second vias 340. Accordingly, a portion of the mold layer 400, which is located on the top surfaces of the first vias 240 and the top surfaces of the second vias 340, may be removed. The top surface of the mold layer 400 may be coplanar with the top surfaces of the first vias 240 and the top surfaces of the second vias 340.

In an embodiment, the mold layer 400, which is disposed on the first semiconductor chip 200 and the dummy chip 300, may have a flat top surface. For example, the first vias 240 may protrude above the top surface of the first semiconductor substrate 210, and the second vias 340 may protrude above the top surface of the second semiconductor substrate 310. The mold layer 400 may cover the top surface of the first semiconductor substrate 210 and the top surface of the second semiconductor substrate 310 and may enclose the first vias 240 and the second vias 340. The mold layer 400 may have a small thickness around the first and second vias 240 and 340 and may be supported by the first semiconductor substrate 210 and the second semiconductor substrate 310. Thus, even when the grinding process or the chemical-mechanical polishing process is performed on the mold layer 400, it may be possible to remove or suppress an undulation issue of the mold layer 400, which may occur on the first semiconductor chip 200 and the dummy chip 300 (in particular, on the top surfaces of the first and second semiconductor substrates 210 and 310). For example, the top surface of the mold layer 400 may have a flat shape on the first semiconductor chip 200 and the dummy chip 300, and this may facilitate a subsequent process of forming the redistribution substrate 100. As a result, it may be possible to reduce the failure rate in the process of fabricating a semiconductor package and increase the structural stability of the semiconductor package.

Referring to FIG. 12, the mold layer 400 may be patterned to form holes exposing the third pads 538 of the second semiconductor chip 500. Here, the holes may have a width that is larger than that of the first vias 240.

A conductive layer may be formed on the mold layer 400. The conductive layer may cover the top surface of the mold layer 400 and may fill the holes. For example, the formation of the conductive layer may include forming a seed layer to conformally cover the top surface of the mold layer 400 and side and bottom surfaces of the holes and performing a plating process using the seed layer as a seed. Next, a portion of the conductive layer, which is placed on the top surface of the mold layer 400 or is depicted by the dotted line of FIG. 11, may be removed to form the conductive posts 450 in the holes.

In an embodiment, the conductive posts 450 may be formed by filling the holes with a conductive material. For example, the conductive posts 450 may be formed by a plating process using the top surfaces of the third pads 538, which are exposed through the bottom surfaces of the holes, as the seed. In this case, the seed layers 452 of FIG. 3 might not be formed.

Next, the redistribution substrate 100 may have the structure shown in FIG. 1.

The redistribution insulating layer 110 may be formed on the mold layer 400, the first semiconductor chip 200, and the dummy chip 300. The redistribution insulating layer 110 may be formed by a deposition process or a coating process. The redistribution conductive pattern 120 may be formed on the redistribution insulating layer 110. For example, the formation of the redistribution conductive pattern 120 may include patterning the redistribution insulating layer 110 to form openings exposing the conductive posts 450, the first vias 240, and the second vias 340, forming a seed layer to conformally cover the top surface of the redistribution insulating layer 110 and the openings, forming a conductive layer, which covers the redistribution insulating layer 110 and is coupled to the conductive posts 450, the first vias 240, and the second vias 340, through a plating process using the seed layer, and patterning the conductive layer.

As a result of the above process, a single substrate interconnection layer, which includes the redistribution insulating layer 110 and the redistribution conductive pattern 120 therein, may be formed on the mold layer 400, the first semiconductor chip 200, and the dummy chip 300. The redistribution substrate 100 may be formed by repeating the process of forming the substrate interconnection layer. The redistribution conductive patterns 120, which are provided in the lowermost one of the substrate interconnection layers, may be used as substrate pads for coupling with the outer terminals 130.

The outer terminals 130 may be coupled to the substrate pads.

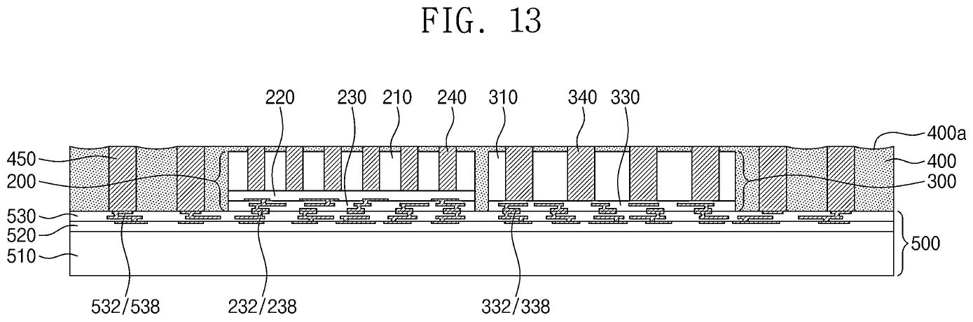

FIG. 13 is a cross-sectional view illustrating a method of fabricating a semiconductor package, according to an embodiment of the inventive concept.

Referring to FIG. 13, the mold layer 400, which is included in the resulting structure of FIG. 10, may be partially removed. For example, a grinding process or a chemical-mechanical polishing (CMP) process may be performed on the top surface of the mold layer 400. The grinding process or the chemical-mechanical polishing process may be performed to expose the first vias 240 and the second vias 340. Accordingly, a portion of the mold layer 400 may be removed from a region on the top surfaces of the first vias 240 and the top surfaces of the second vias 340. The top surface of the mold layer 400 may be coplanar with the top surfaces of the first vias 240 and the top surfaces of the second vias 340.

At least a portion 400a of the top surface of the mold layer 400 might not be flat. The top surface of the mold layer 400 may be flat on the first semiconductor chip 200 and the dummy chip 300, and the top surface 400a of the mold layer 400 may be concave at a side of the first semiconductor chip 200 and the dummy chip 300. As an example, the top surface 400a of the mold layer 400 may be concave between the conductive posts 450 and between the conductive posts 450 and the side surface of the mold layer 400. For example, when the grinding process or the chemical-mechanical polishing process is performed, the mold layer 400 may be over-etched between the conductive posts 450 and between the conductive posts 450 and the side surface of the mold layer 400. Since a distance between the conductive posts 450 is large and a thickness of the mold layer 400 between the conductive posts 450 is large, the mold layer 400 may be over-etched between the conductive posts 450 and between the conductive posts 450 and the side surface of the mold layer 400.

When the grinding process or the chemical-mechanical polishing process is performed, the top surface of the mold layer 400 may be flat between the first vias 240 and between the second vias 340. Since a distance between the first vias 240 and a distance between the second vias 340 are large and a thickness of the mold layer 400 is small between the first vias 240 and between the second vias 340, an etching depth of the mold layer 400 may be uniform between the first vias 240 and between the second vias 340.

Referring back to FIG. 5, the redistribution substrate 100 may be formed. The redistribution insulating layer 110 may be formed on the mold layer 400, the first semiconductor chip 200, and the dummy chip 300. The redistribution conductive pattern 120 may be formed on the redistribution insulating layer 110. A substrate interconnection layer, which includes the redistribution insulating layer 110 and the redistribution conductive pattern 120 in the redistribution insulating layer 110, may be formed on the mold layer 400, the first semiconductor chip 200, and the dummy chip 300. The redistribution substrate 100 may be formed by repeating the process of forming the substrate interconnection layer. The outer terminals 130 may be coupled to the substrate pads.

According to an embodiment of the inventive concept, even when the grinding process or the chemical-mechanical polishing process is performed in an over-etching manner, the mold layer 400 may have a uniform thickness below the first semiconductor chip 200 and the dummy chip 300 and may have a flat surface proximate to the first semiconductor chip 200 and the dummy chip 300. Thus, the substrate interconnection layers in the redistribution substrate 100, which is formed on the mold layer 400, may also be flat. As a result, it may be possible to reduce a failure rate in a process of fabricating a semiconductor package and realize a semiconductor package with increased structural stability.

In a semiconductor package, according to an embodiment of the inventive concept, a front surface of a first semiconductor chip may be directly connected to a front surface of a second semiconductor chip. Thus, a length of an electric connection path between the first semiconductor chip and the second semiconductor chip may be reduced. In addition, a dummy chip may directly connect the second semiconductor chip to a redistribution substrate, and a width of vias in the dummy chip may be larger than a width of vias in the first semiconductor chip with integrated circuits. Thus, it may be possible to reduce an electrical resistance of an interconnection line in the dummy chip and an electrical resistance of an electric path between the second semiconductor chip and the redistribution substrate. For example, it may be possible to enhance the electrical characteristics of the semiconductor package. Furthermore, in a region where it is difficult to provide the dummy chip in the form of a chip, conductive posts may have a width that is larger than a width of the vias of the first semiconductor chip. An electrical resistance of an electric path between the second semiconductor chip and the redistribution substrate passing through the conductive posts may be smaller than an electrical resistance of an electric path between the second semiconductor chip and the redistribution substrate passing through the first semiconductor chip. For example, an electric path between the second semiconductor chip and the redistribution substrate may have a sufficiently low electrical resistance in all regions except for the region containing the first semiconductor chip with integrated circuits, and this may make it possible to realize a semiconductor package with enhanced electrical characteristics.

In a method of fabricating a semiconductor package according to an embodiment of the inventive concept, even when a grinding process or a chemical-mechanical polishing process is performed in an over-etching manner, the mold layer may have a uniform thickness below the first semiconductor chip and the dummy chip and may have a flat surface proximate to the first semiconductor chip and the dummy chip. Thus, the substrate interconnection layers in the redistribution substrate, which is formed on the mold layer, may also be flat. As a result, it may be possible to reduce a failure rate in a process of fabricating a semiconductor package and realize a semiconductor package with increased structural stability.

While example embodiments of the inventive concept have been particularly shown and described, it will be understood by one of ordinary skill in the art that variations in form and detail may be made therein without departing from the spirit and scope of the present disclosure.

1. A semiconductor package, comprising:
a first semiconductor chip;
a second semiconductor chip disposed on an active surface of the first semiconductor chip;
a dummy chip disposed on the active surface of the first semiconductor chip and horizontally spaced apart from the second semiconductor chip;
a mold layer disposed on the active surface of the first semiconductor chip and enclosing both the second semiconductor chip and the dummy chip; and
a conductive post vertically penetrating the mold layer proximate to the second semiconductor chip and the dummy chip coupled to the active surface of the first semiconductor chip,
wherein an active surface of the second semiconductor chip and an active surface of the dummy chip are each in direct contact with the active surface of the first semiconductor chip,
wherein the dummy chip comprises a first via vertically penetrating the dummy chip, the first via being exposed to a region on a top surface of the dummy chip,
wherein the second semiconductor chip comprises a second via vertically penetrating the second semiconductor chip, the second via being exposed to a region on a top surface of the second semiconductor chip, and
wherein a first width of the first via is larger than a second width of the second via.

2. The semiconductor package of claim 1, wherein a third width of the conductive post is larger than the second width of the second via.

3. The semiconductor package of claim 2, wherein the third width of the conductive post is substantially equal to the first width of the first via.

4. The semiconductor package of claim 1, wherein the first width of the first via is 5 to 50 times larger than the second width of the second via.

5. The semiconductor package of claim 4, wherein the first width of the first via ranges from 10 μm to 100 μm, and
wherein the second width of the second via ranges from 0.2 μm to 2 μm.

6. The semiconductor package of claim 1, wherein the first via comprises a protruding portion extended to a region on the top surface of the dummy chip, and
wherein the second via comprises a protruding portion extended to a region on the top surface of the second semiconductor chip.

7. The semiconductor package of claim 6, wherein the mold layer covers both the top surface of the dummy chip and the top surface of the second semiconductor chip, and
wherein the first via and the second via are exposed to a region on a top surface of the mold layer.

8. The semiconductor package of claim 1, further comprising:
a redistribution substrate disposed on the mold layer; and
outer terminals disposed on a top surface of the redistribution substrate,
wherein the first via, the second via, and the conductive post are each coupled to the redistribution substrate.

9. The semiconductor package of claim 8, wherein the first semiconductor chip is electrically connected to the redistribution substrate through the first via of the dummy chip and the conductive post,
wherein the dummy chip is configured to deliver an operation signal of the first semiconductor chip, and
wherein the conductive post is configured to deliver a power/ground signal of the first semiconductor chip.

10. The semiconductor package of claim 1, wherein a top surface of the mold layer is substantially flat on the second semiconductor chip and the dummy chip, and
wherein the top surface of the mold layer is concave at a side of the second semiconductor chip and the dummy chip.

11. The semiconductor package of claim 1, wherein, at an interface between the first semiconductor chip and the second semiconductor chip, first chip pads of the first semiconductor chip and second chip pads of the second semiconductor chip are in direct contact with each other and form a single object, and
wherein at an interface between the first semiconductor chip and the dummy chip, third chip pads of the first semiconductor chip and fourth chip pads of the dummy chip are in contact with each other and form a single object.

12. A semiconductor package, comprising:
a redistribution substrate;
a first semiconductor chip disposed on the redistribution substrate;
a dummy chip disposed on the redistribution substrate and horizontally spaced apart from the first semiconductor chip;
a second semiconductor chip disposed on both the first semiconductor chip and the dummy chip;
a mold layer filling a space between the redistribution substrate and the second semiconductor chip; and
outer terminals disposed on a bottom surface of the redistribution substrate,
wherein the first semiconductor chip comprises:
a first semiconductor substrate;
a first circuit layer disposed on the first semiconductor substrate;
first pads disposed on a top surface of the first circuit layer; and
first vias vertically penetrating the first semiconductor substrate and coupled to the first circuit layer,
wherein the dummy chip comprises:
a second semiconductor substrate;
second pads disposed on the second semiconductor substrate; and
second vias vertically penetrating the second semiconductor substrate and electrically connected to the second pads,
wherein the first pads and the second pads are in contact with third pads of the second semiconductor chip, and
wherein a width of the second vias is 5 to 50 times larger than a width of the first vias.

13. The semiconductor package of claim 12, further comprising a conductive post vertically penetrating the mold layer and connecting the redistribution substrate to the second semiconductor chip,
wherein a width of the conductive post is larger than the width of the first vias.

14. The semiconductor package of claim 13, wherein the width of the conductive post is substantially equal to the width of the second vias.

15. The semiconductor package of claim 12, wherein the width of the second vias ranges from 10 μm to 100 μm, and
wherein the width of the first vias ranges from 0.2 μm to 2 μm.

16. The semiconductor package of claim 12, wherein the first vias are extended to a region below a bottom surface of the first semiconductor substrate,
wherein the second vias are extended to a region below a bottom surface of the second semiconductor substrate, and
wherein the mold layer covers the bottom surface of the first semiconductor substrate and the bottom surface of the second semiconductor substrate and encloses the first vias and the second vias.

17. The semiconductor package of claim 16, wherein, below the first semiconductor substrate, the first vias penetrate the mold layer and are connected to the redistribution substrate, and
wherein below the second semiconductor substrate, the second vias penetrate the mold layer and are connected to the redistribution substrate.

18. The semiconductor package of claim 12, wherein the second semiconductor chip is electrically connected to the redistribution substrate through the second vias of the dummy chip and the conductive post,
wherein the dummy chip is configured to deliver an operation signal of the second semiconductor chip, and
wherein the conductive post is configured to deliver a power/ground signal of the second semiconductor chip.

19. The semiconductor package of claim 12, wherein at an interface between the first semiconductor chip and the second semiconductor chip, the first pads and the third pads are in direct contact with each other and form a single object, and
wherein at an interface between the second semiconductor chip and the dummy chip, the second pads and the third chip pads are in contact with each other and form a single object.

20. A semiconductor package, comprising:
a redistribution substrate;
a first semiconductor chip and a dummy chip disposed on the redistribution substrate and spaced apart from each other;
a second semiconductor chip covering both the first semiconductor chip and the dummy chip;
a mold layer filling a space between the redistribution substrate and the second semiconductor chip; and
a conductive post vertically penetrating the mold layer and connecting the redistribution substrate to the second semiconductor chip,
wherein the first semiconductor chip comprises:
a first semiconductor substrate, including an integrated circuit formed on a top surface thereof facing the second semiconductor chip; and
a first circuit layer disposed on the top surface of the first semiconductor substrate and electrically connected to the integrated circuit,
wherein the dummy chip comprises:
the second semiconductor substrate;
a second circuit layer disposed on a top surface of the second semiconductor substrate; and
first vias vertically penetrating the second semiconductor substrate and connected to the second circuit layer, the first vias comprising protruding portions extended to a region below a bottom surface of the second semiconductor substrate,
wherein a width of the first vias is substantially equal to or larger than a width of the conductive post.

21-25. (canceled)
